(19) United States
(12) Patent Application Publication
(10) Pub. No.: US 2026/0255688 A1
(43) Pub. Date: Aug. 27, 2026

(54) DIODE-TRIGGERED SILICON CONTROLLED-RECTIFIER IN FRONT VIA BACKSIDE POWER TECHNOLOGY

(71) Applicant: INTERNATIONAL BUSINESS MACHINES CORPORATION, ARMONK, NY (US)

(72) Inventors: Anindya Nath, Watervliet, NY (US); Robert Gauthier, Williston, VT (US); Masoud Zabihi, Schenectady, NY (US); Anthony I-Chih Chou, Guilderland, NY (US)

(21) Appl. No.: 19/063,225

(22) Filed: Feb. 25, 2025

(51) Int. Cl. H10D 89/60; H01L 21/768; H01L 23/522; H01L 23/528

(52) U.S. Cl. CPC H10D 89/713; H10D 89/611; H10W 20/076; H10W 20/42; H10W 20/427

(57) ABSTRACT

A semiconductor device includes a silicon controlled rectifier (SCR) including a P-type doped region and an N-type doped region, an N-well region, a P-well region adjacent to the N-well region, a set of shallow trench isolation (STI) below the P-type doped region and the N-type doped region and within the N-well region and the P-well region, and a first diode and a second diode coupled in series to the SCR. The SCR, the first diode and the second diode are isolated by a set of vias extended vertically from a frontside of the semiconductor device to a backside of the semiconductor device.

### BACKGROUND

### Technical Field

The present disclosure generally relates to semiconductors, and more particularly, to diode-triggered silicon-controlled rectifier in front via backside power structure, and methods of creation thereof.

### Description of Related Art

The continuous miniaturization of transistors and their increasing density on chips are hallmark innovations in the semiconductor industry, closely following Moore's Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a silicon controlled rectifier (SCR) including a P-type doped region and an N-type doped region, an N-well region, a P-well region adjacent to the N-well region, a set of shallow trench isolation (STI) below the P-type doped region and the N-type doped region and within the N-well region and the P-well region, and a first diode and second diode couped in series to the SCR. The SCR, the first diode and the second diode are isolated by a set of vias extended vertically from a frontside of the semiconductor device to a backside of the semiconductor device.

In one embodiment, the semiconductor device includes gate regions on opposite ends of the N-type doped region and the P-type doped region.

In one embodiment, the semiconductor device includes a backside interlayer dielectric below the N-well region and the P-well region.

In one embodiment, each of the N-type doped region and the P-type doped region includes a plurality of nano-sheet channels between a corresponding doped region and a gate region.

In one embodiment, the plurality of nano-sheet channels includes alternative layers extended horizontally between the corresponding doped region and the gate region.

In one embodiment, the alternative layers include silicon.

In some embodiments, the logic device is isolated from the second diode by a via, and the set of vias are configured to provide electrical connection between the frontside to the backside.

According to an embodiment, a method of fabricating a semiconductor device includes forming a silicon controlled rectifier (SCR) including forming a P-type doped region and an N-type doped region, forming an N-well region, forming a P-well region adjacent to the N-well region, forming a set of shallow trench isolation (STI) below the P-type doped region and the N-type doped region and within the N-well region and the P-well region, forming a first diode and a second diode coupled in series to the SCR, isolating the SCR, the first diode and the second diode by a set of vias extended vertically from a frontside of the semiconductor device to a backside of the semiconductor device,

In one embodiment, the method includes forming gate regions on opposite ends of the N-type doped region and the P-type doped region.

In one embodiment, the method includes forming a backside interlayer dielectric below the N-well region and the P-well region.

In one embodiment, forming each of the N-type doped region and the P-type doped region includes forming a plurality of nano-sheet channels between a corresponding doped region and a gate region.

In one embodiment, forming the plurality of nano-sheet channels includes extending alternative layers horizontally between the corresponding doped region and the gate region.

In one embodiment, the alternative layers include silicon.

In one embodiment, the method includes forming a logic device coupled to the second diode, and forming a liner over sidewalls of each of the set of vias. The liner includes SiN.

In some embodiments, the method includes isolating the logic device from the second diode by a via, and providing electrical connections between the frontside and the backside by the set of vias.

According to an embodiment, a semiconductor device includes a silicon controlled rectifier (SCR), a diode coupled in series to the SCR and a bipolar junction transistor coupled in series to the diode. The SCR and the diode/diodes are isolated by a set of vias and a set of shallow trench isolation. P-wells of the SCR and the bipolar junction transistor are coupled in the direction into the screen.

In an embodiment, the SCR includes a P-type doped region and an N-type doped region, an N-well region, a P-well region adjacent to the N-well region, wherein the N-well region and the P-well region are located below the P-type doped region and the N-type doped region. The set of shallow trench isolation are located below the P-type doped region and the N-type doped region and within the N-well region and the P-well region.

In one embodiment, the semiconductor device includes gate regions on opposite ends of the N-type doped region and the P-type doped region, and a backside interlayer dielectric below the N-well region and the P-well region.

In one embodiment, each of the N-type doped region and the P-type doped region includes a plurality of nano-sheet channels between a corresponding doped region and a gate region.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates circuitry of an ESD device.

FIG. 1B illustrates schematically an ESD device operation during the normal circuit operation voltage range, ESD operating window during an ESD event, and the failure region.

FIG. 2A illustrates a conventional bipolar string triggered electrostatic discharge device.

FIG. 2B illustrates circuitry of an SCR portion of a conventional bipolar string triggered electrostatic discharge device.

FIG. 2C illustrates the circuitry of VNPN portion of a conventional bipolar string triggered electrostatic discharge device.

FIG. 2D illustrates a circuitry of the semiconductor device shown in FIG. 2A.

FIG. 2E is an I-V graph of the semiconductor device shown in FIG. 2A.

FIG. 3A-3D illustrate a semiconductor device, in accordance with an embodiment.

FIG. 4A-4C illustrates exemplary circuitry of the semiconductor device shown in FIGS. 3A-3D, respectively.

FIG. 5 illustrates a block diagram of a method for forming the semiconductor device, in accordance with an embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

In foundry technology, developing a complete portfolio of electrostatic discharge (ESD) protection devices is important to support the diverse types of input/output (I/O) configurations used in advanced semiconductor designs. ESD protection devices can safeguard sensitive electronic components against high-voltage spikes and unintended electrical discharges, which can occur during manufacturing, assembly, or end-use handling. As technology scales down to nodes such as 2 nm and below, achieving robust ESD protection becomes increasingly challenging due to the ultra-small geometries and reduced breakdown voltages of modern transistors.

Key types of ESD devices for a comprehensive protection solution include NPNP or PNPN structures, which are typically implemented as thyristors or silicon-controlled rectifiers (SCRs). These devices, characterized by their four-layer structure of alternating P-and N-type regions, can absorb and divert large amounts of charge during an ESD event. The thyristor, in particular, operates as a controlled switch with two stable states, enabling it to withstand high-voltage transients without triggering during normal circuit operation. An SCR, on the other hand, offers even more robust ESD protection, as it can latch into a low-resistance state when triggered, allowing it to handle higher current levels than typical ESD diodes or resistive networks. However, as scaling progresses to the 2 nm node and below, there are disadvantages in current technology such as the breakdown voltage, leakage characteristics, and latch-up immunity of the devices.

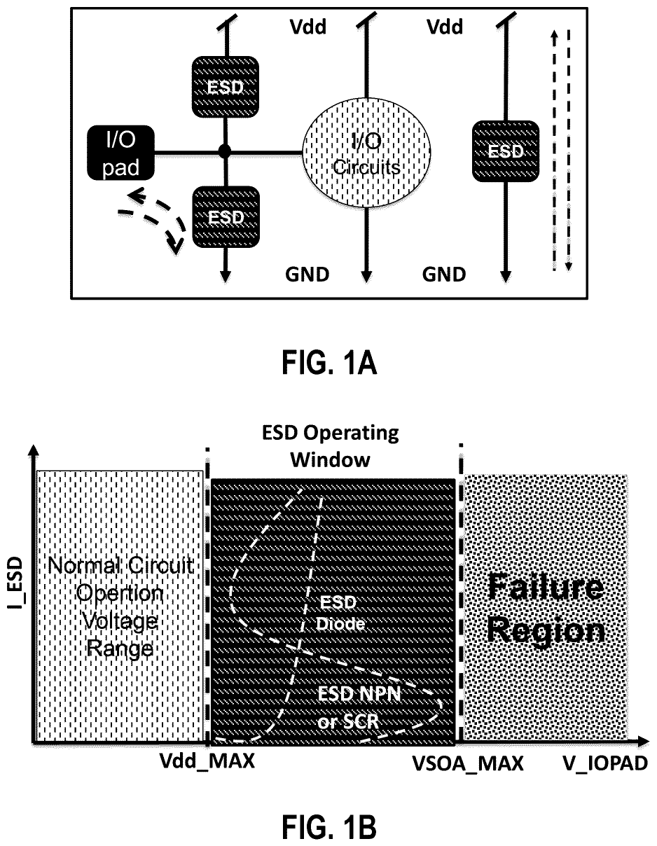

FIG. 1A illustrates circuitry of an ESD device, and FIG. 1B illustrates schematically an ESD device operation during the normal circuit operation voltage range, ESD operating window during an ESD event, and the failure region.

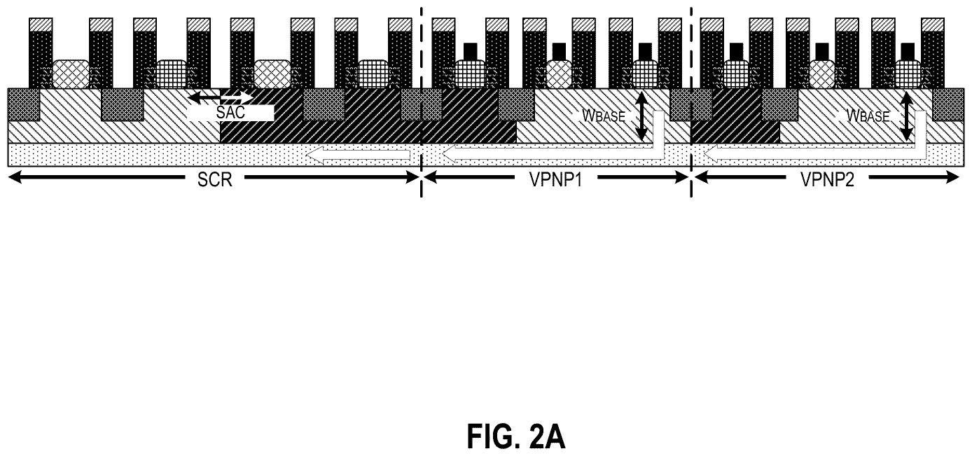

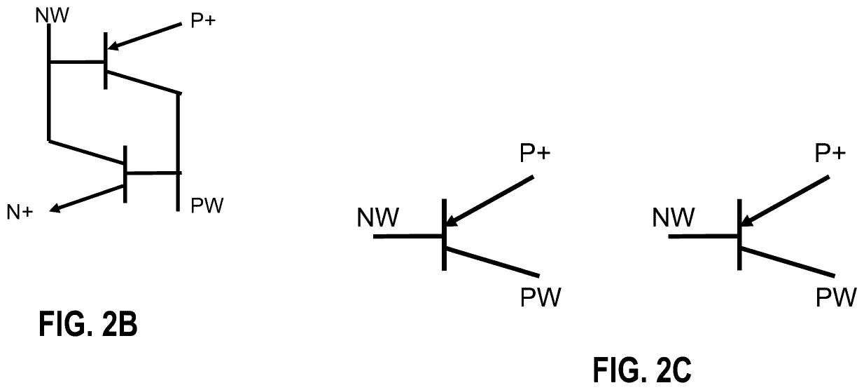

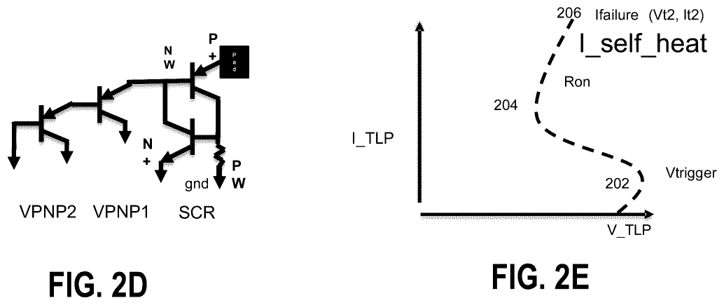

FIG. 2A illustrates a conventional diode/bipolar string triggered electrostatic discharge device. FIG. 2B illustrates circuitry of an SCR portion of a conventional bipolar string triggered electrostatic discharge device. FIG. 2C illustrates the circuitry of VNPN portion of a conventional bipolar string triggered electrostatic discharge device. A diode/bipolar string-triggered electrostatic discharge (ESD) protection device is designed to safeguard sensitive electronic components from voltage spikes due to ESD events by creating a controlled discharge path that diverts excessive current safely away from protected circuitry. Under normal operating conditions, the ESD protection device remains in a high-impedance, non-conductive state, isolating itself from the circuit to prevent interference with the device's usual functionality. The diode or bipolar junction transistor (BJT) string is reverse-biased or configured in such a way that it does not conduct any significant current, e.g., 1 micro-Ampere or less, under standard voltage levels, ensuring that the protection device remains inactive. FIG. 2D illustrates a circuitry of the semiconductor device shown in FIG. 2A.

FIG. 2E is an I-V graph of the semiconductor device shown in FIG. 2A. The I-V graph of a diode/bipolar string triggered ESD protection device typically exhibits distinct regions that correspond to its behavior under varying voltage and current conditions. At the pre-trigger current region (point 202), the device is in its off state, with only a small leakage current flowing through it. This is typically a low-current, high-resistance state. The voltage increases with minimal current flow until it reaches the trigger voltage. At the snap-back region (from point 202 to point 204), as the voltage reaches the trigger threshold, the device transitions into conduction mode. This region is characterized by negative resistance, where an increase in current results in a decrease in voltage across the device. This snap-back effect occurs due to the activation of the bipolar transistor within the structure, which leads to a significant reduction in the device's resistance and allows current to flow more freely. At the high current conduction region (from point 204 to point 206), the device conducts high levels of current as it clamps the voltage at a safe level to protect downstream circuitry. The onset of self-heating becomes evident as the device handles high currents, which may result in a slight upward curvature in the I-V characteristic due to thermal effects increasing the resistance slightly.

When an ESD event occurs, it introduces a rapid and high-voltage spike, which can be (by way of example and not limitation) between 2,000 to 25,000 volts and at rise times of 0.7 to 100 nanosecond (ns) at an input/output (I/O) pin or power rail, often originating from a charged object such as a human body or another conductive item. This voltage spike, significantly higher than the circuit's operating range, is sensed by the ESD device. The protection mechanism in the diode or BJT string is designed with a breakdown threshold slightly above the normal operating voltage yet below levels that would be damaging to the circuitry. As the ESD voltage climbs and reaches this breakdown threshold, the diodes or BJTs in the string enter a breakdown mode, creating a conductive path for the transient current.

In a diode string, each diode, e.g., VPNP1 and VPNP2, undergoes reverse breakdown as the ESD voltage exceeds the threshold, providing a low-resistance discharge path for the ESD current. Alternatively, in a bipolar string, each transistor becomes forward biased under the ESD voltage, behaving like a switch that enables a continuous current path from the ESD event to ground. The bipolar junction transistors are designed to “turn on” when the ESD voltage rises above the safe operating threshold, allowing them to conduct high currents briefly, which safely dissipates the excess charge. This controlled conduction prevents the high voltage from reaching sensitive areas in the circuit.

As the breakdown occurs, the ESD device provides a low-resistance path through the diode or BJT string, effectively shunting the excessive ESD current away from the sensitive parts of the circuit to a ground or designated power rail. In a diode string, each diode breakdown stage sequentially reduces the resistance, directing the current through the device without allowing high voltage to interfere with the protected circuit. In a bipolar string, each forward-biased transistor acts collectively to create a low-resistance path that can handle substantial current flow (e.g., 1-12 amps during peak currents) for the brief duration of the ESD event.

Once the ESD event has dissipated and the voltage level returns to its normal range, the diode or BJT string exits its breakdown or forward-biased state. The device then reverts to a high-impedance mode, disconnecting from the circuit and resuming its inactive state. With the high impedance restored, the ESD protection device does not influence normal circuit operation and is now ready to protect against any future ESD events without impacting the regular functionality of the protected circuitry.

For a foundry technology, a typical ESD protection device must accommodate the standard I/O types designed for various semiconductor applications. A crucial requirement for these ESD devices is the inclusion of a low-voltage trigger SCR, such as a diode-triggered SCR. The low-voltage trigger SCR is essential for providing effective protection against transient voltage spikes that can occur during normal operation or handling of electronic components. This type of SCR activates at lower voltages, ensuring that the ESD protection engages promptly to safeguard the semiconductor devices from potential damage. However, the fabrication of trigger diodes within bulk silicon presents significant challenges. When trigger diodes are created in bulk, they inadvertently lead to the Darlington effect. The Darlington effect occurs when two transistors are combined in such a way that their current gains multiply, resulting in a much higher overall gain. While this can be advantageous in certain applications, in the context of ESD protection, it leads to undesirable electrical characteristics. Specifically, the Darlington effect can cause increased leakage currents and slower response times, which are detrimental to the rapid protection required during ESD events.

Moreover, the integration of trigger diodes in bulk silicon contributes to poor scaling. As semiconductor technology advances, there is a continuous push towards smaller feature sizes and higher integration densities. Poor scaling refers to the difficulty in maintaining performance and reliability as device dimensions shrink. In the case of bulk-triggered diodes, the larger physical size and inherent electrical properties hinder the ability to scale down effectively, limiting the overall efficiency and performance of the ESD protection mechanism.

Disclosed is a semiconductor device integrating an SCR as a fundamental component within its architecture. The SCR can manage and control electrical current flow within the device, acting as a high-power switching element capable of handling substantial voltages and currents. This SCR is connected in series with a combination of diodes, forming a protective and regulatory pathway for electrical signals. The diodes, integral to this configuration, serve to direct the flow of current in a specific direction, preventing undesired reverse currents that could potentially disrupt the device's operation or damage sensitive components.

The diodes within this arrangement are isolated by front-via-backside-power (FVBP) floating contacts, a feature designed to enhance the device's electrical isolation and stability. FVBP floating contacts function by creating an insulated bridge between the front and backside power layers of the semiconductor substrate. This isolation can facilitate preventing electrical interference and ensuring that the diodes operate efficiently without unintended interactions with other parts of the circuitry. By maintaining electrical separation, the FVBP floating contacts contribute to the overall reliability and performance of the device, minimizing the risk of electrical noise and signal degradation.

Adjacent to this configuration can be the vertical bipolar transistors (VPNPs), which are vertically integrated into the semiconductor substrate to provide efficient amplification and switching capabilities. These VPNPs are engineered to handle high-frequency signals with minimal distortion, making them ideal for applications that demand rapid signal processing and high-speed communication. The vertical integration of these bipolar transistors allows for a more compact and efficient design, enabling higher density of components within the semiconductor device without compromising on performance or thermal management.

The integration of the SCR, diodes, FVBP floating contacts, and VPNPs creates an electrical network within the semiconductor device, optimized for high reliability and performance. The SCR acts as a protective switch, activating during overcurrent conditions to safeguard the device from potential electrical surges. The diodes ensure that current flows in the intended direction, maintaining the integrity of the electrical pathways and preventing backflow that could disrupt normal operation. The FVBP floating contacts provide the necessary isolation between different power layers, enhancing the stability of the electrical connections and reducing the risk of interference. Meanwhile, the VPNPs deliver high-speed signal amplification and switching, supporting the device's ability to handle complex and high-frequency operations.

This combination of components addresses challenges in semiconductor device design. By incorporating an SCR connected in series with diodes, the device gains robust protection against electrostatic discharge and other transient voltage events that could otherwise damage the circuitry. The FVBP floating contacts further enhance this protection by ensuring that the diodes remain isolated from other power layers, preventing unintended interactions and maintaining the device's overall stability. The inclusion of VPNPs provides the necessary amplification and switching capabilities to support high-speed data processing and communication, which are essential for modern electronic applications that require rapid and reliable performance.

The fabrication of this semiconductor device involves advanced manufacturing techniques to ensure the precise integration and functionality of each component. The SCR is fabricated using high-purity silicon materials to achieve the necessary breakdown voltage and current handling capabilities. The diodes are doped with specific impurities to attain the desired rectifying behavior, ensuring efficient current direction and minimal leakage. The FVBP floating contacts are meticulously patterned and insulated to maintain their electrical isolation, requiring precise control over the deposition and etching processes. The VPNPs are created using vertical integration methods that allow for dense packing and efficient electrical interconnections, maximizing the device's performance potential.

Moreover, the design of the semiconductor device emphasizes scalability and adaptability, allowing it to be utilized in various applications ranging from consumer electronics to industrial automation and high-performance computing. The integration of the SCR, diodes, FVBP floating contacts, and VPNPs provides a versatile platform that can be tailored to meet specific performance criteria and operational requirements. This adaptability is important in the rapidly evolving semiconductor industry, where devices must continuously advance to keep pace with emerging technologies and increasing demands for speed, efficiency, and reliability.

The elimination of traditional bulk-triggered diodes in favor of the FVBP floating contacts and the integration of vertical bipolar transistors represent significant innovations in semiconductor device design. These advancements enhance the device's electrical performance and contribute to its mechanical and thermal stability. By reducing the reliance on bulk-triggered components, the device achieves better scalability, allowing for smaller feature sizes and higher integration densities without sacrificing performance or reliability. This streamlined approach also simplifies the manufacturing process, reducing the complexity and cost associated with traditional ESD protection methods and enabling more efficient production workflows.

In addition to their individual functions, the harmonious interaction between the SCR, diodes, FVBP floating contacts, and VPNPs ensures that the semiconductor device operates seamlessly under a wide range of conditions. The SCR provides a fail-safe mechanism that activates during overcurrent events, while the diodes maintain controlled current flow under normal operating conditions. The FVBP floating contacts facilitate seamless power distribution across the device's layers, and the VPNPs ensure that high-speed signals are accurately amplified and routed. This integrated approach not only enhances the device's electrical performance but also ensures that it can operate reliably under varying environmental and operational conditions.

Furthermore, the design and fabrication of this semiconductor device prioritize thermal management to prevent overheating and ensure optimal performance. The vertical integration of the bipolar transistors allows for efficient heat dissipation, reducing thermal resistance and enhancing the device's ability to maintain stable operating temperatures. The careful selection of materials and precise manufacturing processes contribute to the device's overall thermal efficiency, ensuring that it remains within safe temperature ranges even during high-performance operations.

Accordingly, the teachings herein provide methods and systems of diode-triggered SCR in front via backside power structure. The techniques described herein may be implemented in a number of ways. Example implementations are provided below with reference to the following figures.

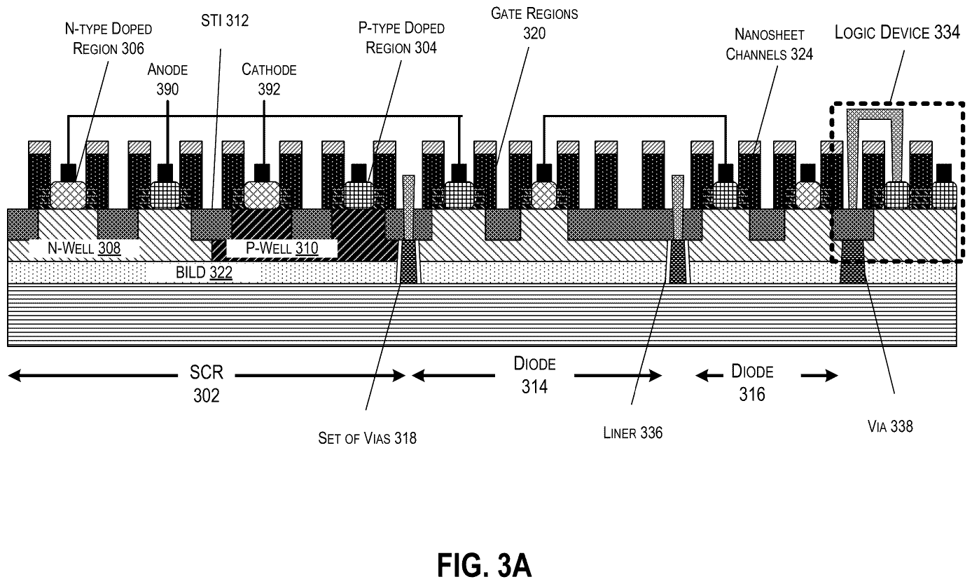

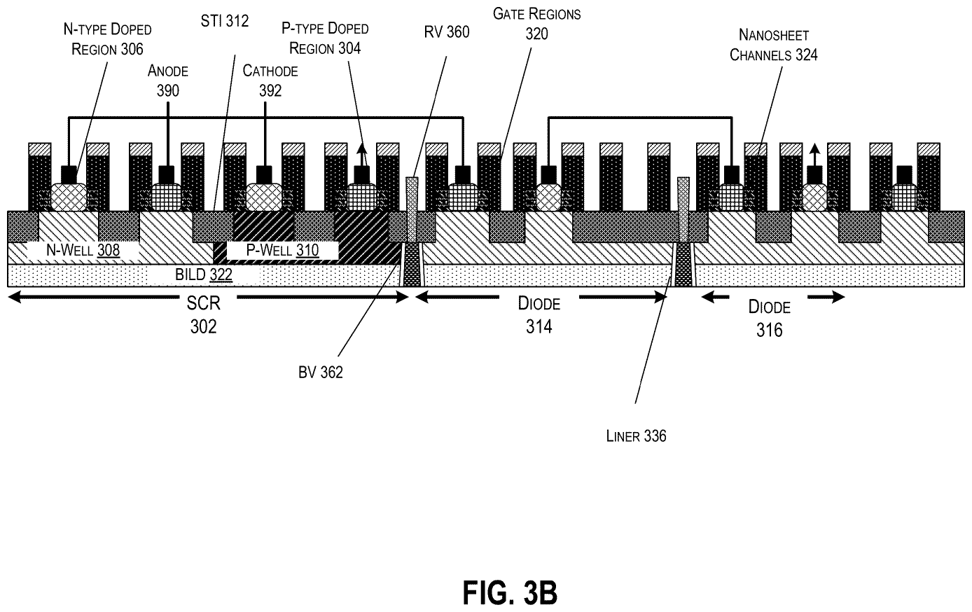

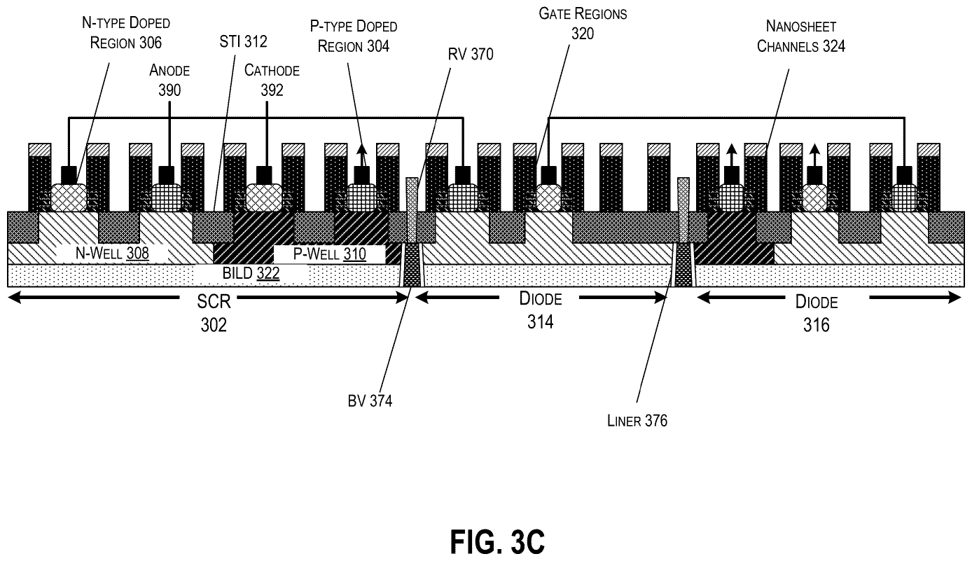

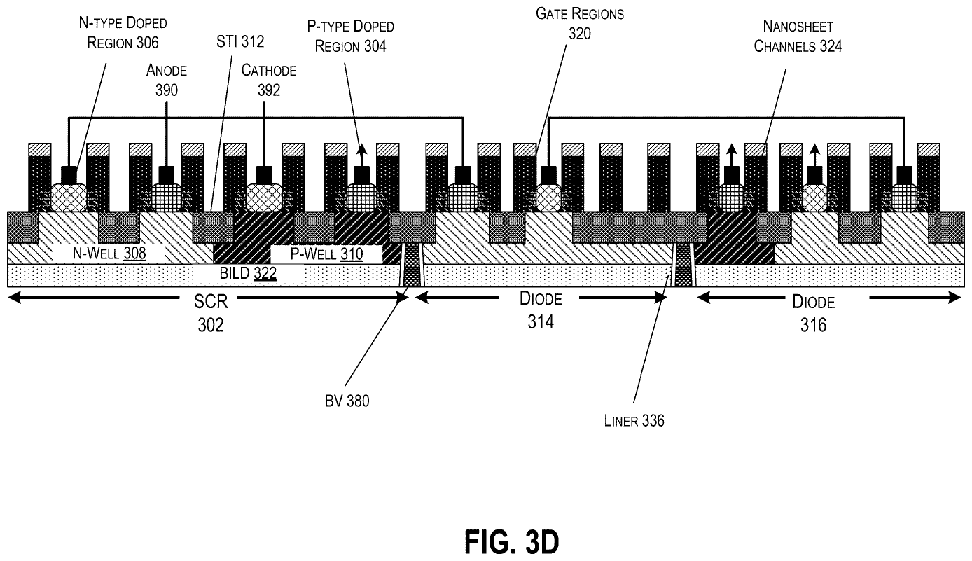

Reference now is made to FIGS. 3A-3D, which provides a cross-section views of a semiconductor device, consistent with illustrative embodiments. FIG. 3A illustrates a semiconductor device with tow diodes coupled to a silicon controlled rectifier in series, in accordance with an embodiment. In some embodiments, the semiconductor device includes a silicon controlled rectifier, SCR 302. The SCR includes a P-type doped region 304 (and the Anode 390) and an N-type doped region 306 (and the Cathode 392). The P-type doped region 304 and the N-type doped region 306 are arranged to form the fundamental structure of the SCR 302, enabling it to control the well-bias, hence the flow of electrical current within the device. The P-type doped region 304 is characterized by an abundance of holes, which are positive charge carriers, while the N-type doped region 306 contains an excess of electrons, serving as negative charge carriers. The interaction between these regions allows the SCR 302 to function effectively as a switching device, regulating the conduction of current based on external signals.

Adjacent to the SCR 302 is an N-well region 308 and a P-well region 310. The N-well region 308 serves as a region for accommodating N-type dopants, enhancing the device's ability to manage and distribute electrical charges. Similarly, the P-well region 310 is doped with P-type impurities, facilitating the creation of P-type environments essential for the operation of the SCR 302 and associated components. The well regions are integral in defining the electrical characteristics and performance of the semiconductor device, ensuring proper isolation and functionality of the active regions. Located beneath both the P-type doped region 304 and the N-type doped region 306 is a set of shallow trench isolation, STI 312. The shallow trench isolation is fabricated within the N-well region 308 and the P-well region 310, providing electrical isolation between adjacent devices and preventing unwanted current leakage. The STI 312 can maintain the integrity of the device by confining electrical activity within specific regions, thereby enhancing the overall performance and reliability of the semiconductor device. By isolating the doped regions, the STI 312 ensures that each SCR 302 operates independently, reducing the risk of interference and cross-talk between neighboring components.

In some embodiments, the semiconductor device includes a first diode 314 and a second diode 316, which are coupled in series with the SCR 302. The first diode 314 and the second diode 316 are integral components of the ESD protection mechanism within the device. These diodes are connected in such a manner that they facilitate unidirectional current flow, and controls the triggering voltage of the SCR, hence enables the SCR's ability to protect the device from electrostatic discharge events. The diodes work in tandem with the SCR to ensure that transient voltage spikes are effectively managed, preventing potential damage to sensitive circuitry. The parallel configuration of the diodes with the SCR provides a robust pathway for current regulation, contributing to the device's overall stability and longevity.

The SCR 302, the first diode 314, and the second diode 316 are electrically isolated by a set of vias 318. These vias extend vertically from the frontside of the semiconductor device to the backside, ensuring that the SCR and diodes are effectively separated from other components within the device. The isolation provided by the set of vias 318 can facilitate maintaining the electrical integrity of the SCR and diodes, preventing unintended interactions with surrounding circuitry. This vertical isolation technique enhances the device's ability to handle high-stress electrical conditions, ensuring reliable performance under varying operational scenarios. In some embodiments, the isolated two-terminal diodes eliminate the Darlington effect commonly seen in bipolar junction transistors used as triggering elements, allowing for linear scaling of the trigger voltage with the number of diodes.

In some embodiments, the semiconductor device includes gate regions 320 positioned on opposite ends of the N-type doped region 306 and the P-type doped region 304. These gate regions 320. The gate regions 320 are electrically isolated dummy gates, used to promote high-quality epi growth to serve as diffusion regions.

In some embodiments, the semiconductor device includes a backside interlayer dielectric 322 positioned below the N-well region and the P-well region. This backside interlayer dielectric 322 enhances the overall performance and reliability of the semiconductor device. Positioned beneath the well regions, the backside interlayer dielectric 322 serves as an insulating barrier that separates the active doping areas from the underlying layers, thereby preventing unintended electrical interactions and minimizing leakage currents. This insulation is important for maintaining the integrity of the electrical characteristics of the N-well and P-well regions, ensuring that they operate within their designated parameters without interference from the substrate.

The backside interlayer dielectric 322 can contribute to the mechanical stability of the semiconductor device. By providing a robust insulating layer, it helps to distribute mechanical stresses evenly across the device, reducing the risk of fractures or deformations that could compromise the functionality of the wells and the overall device structure. This is particularly important in advanced semiconductor technologies where devices are subjected to varying thermal and mechanical conditions during operation. Moreover, the backside interlayer dielectric 322 aids in thermal management by facilitating the dissipation of heat generated within the N-well and P-well regions. Effective heat dissipation is crucial for maintaining optimal operating temperatures, which in turn enhances the performance and longevity of the semiconductor device. The dielectric material chosen for this layer possesses thermal conductivity and stability, ensuring that heat is efficiently conducted away from sensitive areas without introducing thermal resistance that could impede device performance. In addition to electrical insulation and thermal management, the backside interlayer dielectric 322 provides a foundation for subsequent fabrication processes. It offers a smooth and stable surface for the deposition of additional layers, such as metallization or additional dielectric layers, thereby ensuring high precision and uniformity in the manufacturing process. Each of the N-type doped region 306 and the P-type doped region 304 includes a plurality of nano-sheet channels 324. In some embodiments, the nano-sheet channels are inactive for these devices and the current flows through the bulk region.

The plurality of nano-sheet channels includes alternative layers that extend horizontally between the corresponding doped regions and the gate regions. These alternate layers can be composed of silicon, which provides a stable and conductive medium for charge carrier movement for FETs in the logic region The horizontal extension of these layers ensures that the nano-sheet channels maintain consistent electrical characteristics across the device, enabling uniform performance and reliable switching behavior. The arrangement of silicon layers within the nano-sheet channels enhances the device's ability to handle high-frequency signals and rapid current changes, making it suitable for demanding electronic applications.

In some embodiments, the semiconductor device incorporates a logic device 334, which is coupled to the second diode 316. The logic device 334 is responsible for processing and managing electrical signals within the semiconductor device, performing computational tasks that drive the device's functionality. The logic device 334 is integrated with the second diode 316 to ensure seamless communication and control within the electrical network of the device. Additionally, the device includes a liner 336 over the sidewalls of each set of vias 318. The liner 336 can be made of silicon nitride (SiN), which provides electrical insulation and mechanical protection for the vias. The liner 336 enhances the durability and reliability of the set of vias 318, preventing electrical shorting and ensuring robust interconnections between the frontside and backside of the semiconductor device.

The logic device 334 is isolated from the second diode 316 by a via 338, ensuring that the two components operate independently without interference. This isolation is achieved through the placement and fabrication of the via 338, which acts as a barrier between the logic device and the diode. The set of vias 318 are configured to provide electrical connections between the frontside and the backside of the semiconductor device, enabling efficient signal routing and power distribution across different layers of the device. This configuration ensures that the logic device 334 can communicate effectively with other components within the semiconductor device, maintaining high performance and reliability. In some embodiments, each of the N-type doped region 306 and the P-type doped region 304 incorporates a plurality of nano-sheet channels 324 that include alternate layers.

The semiconductor device's architecture, featuring the SCR connected in series with diodes and isolated by vertical vias, provides a framework for managing electrical transients and protecting sensitive components. The inclusion of gate regions on two ends, e.g., opposite ends, of the doped regions allows for precise control over the SCR's operation, while the nano-sheet channels and alternate silicon layers enhance the device's electrical performance. The integration of a logic device coupled to the second diode, along with the SiN liner over the vias, ensures reliable operation and effective signal routing within the device. By isolating the logic device from the second diode through a dedicated via and configuring the set of vias to facilitate frontside-to-backside electrical connections, the semiconductor device achieves high performance, reliability, and scalability, making it well-suited for advanced electronic applications that demand precise current control and robust ESD protection. It should be noted that, the vias can be used to isolate other components of the semiconductor device.

In some embodiments, it will be understood that other types of substrates, other than silicon, may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys. In various embodiments, the substrate can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In some embodiments, each via within the semiconductor device includes a deep via, i.e., RV 360, extending from the frontside of the device to the STI and a backside via, i.e., BV 362, extending from the deep via to the backside of the device. These vias are establish electrical connections between the frontside circuitry and backside components. In the logic device section, the backside via is designed without a liner, making it suitable for backside power delivery network (BSPDN). This configuration facilitates efficient power delivery to the logic circuits, ensuring that the logic device operates reliably without interference from other components. Conversely, in the SCR and diode sections, the backside vias include a liner, typically made of silicon nitride, which serves to electrically isolate these protective elements from the rest of the device. The presence of liners in these vias prevents electrical interference and enhances the reliability of the ESD protection mechanisms. The integration of deep vias and backside vias, along with the backside interlayer dielectric, results in an electrical architecture that supports both efficient power distribution and robust isolation. This design improves the electrical performance and reliability of the semiconductor device and maintains low manufacturing costs and ensures good process compatibility with existing fabrication technologies.

FIG. 3B illustrates a semiconductor device with the set of vias used to BSPDN in logic device and the SCR/diode device section. In some embodiments, as depicted in FIG. 3B, each set of vias within the semiconductor device includes a deep via 360, e.g., RV 360, which extends vertically from the frontside of the device down to the STI 312. From the STI 312, a backside via 362, e.g., BV 362, continues vertically from the deep via 360 to the backside of the semiconductor device. These backside vias are integral to the device's power distribution architecture, facilitating the efficient routing of electrical signals from the frontside circuitry to the backside components. In both the logic device section and the SCR/diode section of the semiconductor device, the backside vias 362 are equipped with liners, typically composed of insulating materials such as silicon nitride. The liner serves to electrically isolate the backside vias from the surrounding substrate and other circuitry, ensuring that power distribution remains stable and free from interference.

By providing electrical isolation, the liner ensures that power is distributed reliably across different sections of the device without causing unintended electrical interactions. The deep via 360 acts as conduits for electrical signals, channeling them from the frontside through the STI and into the backside via 362. Furthermore, the use of deep vias and backside vias with liner in the BSPDN allows for high-density integration and efficient power management. This configuration supports the device's ability to handle high-performance electronic functions while minimizing the risk of electrical interference and signal degradation. The via structure improves power distribution efficiency and contributes to the structural integrity of the semiconductor device by maintaining clear and isolated routing paths. This power distribution system ensures that both the logic and protective SCR/diode sections receive consistent and stable power for optimal operation.

FIG. 3C illustrates a semiconductor device with a bipolar junction transistor coupled to a diode and an SCR. In some embodiments, each via within the semiconductor device includes a deep via 370, e.g., RV 370, which extends vertically from the frontside of the device down to the shallow trench isolation, STI 312. From the STI, a backside via 374, e.g., BV 374, continues vertically from the deep via to the backside of the semiconductor device. The backside via 374 establishes electrical connections between the frontside circuitry and the backside components, facilitating efficient power distribution and signal routing across the device. The backside via 374 in both the logic device section and the SCR/diode section are equipped with liner 376. The liner, which can be made of silicon nitride, provides electrical isolation for the via, ensuring that power distribution remains stable and free from interference. The liner 376 prevents unintended electrical interactions between different sections of the device, enhancing the overall reliability and performance of the semiconductor device. By maintaining electrical isolation, the liner 376 ensures that the backside power delivery network (BSPDN) operates effectively without causing cross-talk or signal degradation between the logic device and the SCR/diode protection mechanisms.

The backside via 374 can be configured to support the BSPDN in both the logic device and the SCR/diode sections. In the logic device section, the backside via 374 facilitates efficient power delivery to the logic circuits, ensuring that the device operates smoothly under various electrical loads. Similarly, in the SCR/diode section, the backside via 374 provides power distribution to the protective elements, enhancing the device's ability to manage electrostatic discharge and transient voltage spikes effectively. Furthermore, the deep via 370 and backside via 374 are fabricated to ensure minimal signal loss and high electrical conductivity. The vertical alignment of these vias from the frontside through the STI to the backside facilitates seamless integration of power and signal pathways, optimizing both electrical performance and thermal management within the device. The integration of deep via 370 and backside via 374 with liner 376 in the logic device and SCR/diode sections establishes a power distribution network within the semiconductor device. This design enhances electrical stability and performance and contributes to the device's scalability and adaptability for advanced electronic applications. By leveraging this via configuration, the semiconductor device achieves a compact and efficient layout, ensuring robust power distribution and signal integrity essential for modern high-speed and high-density semiconductor technologies.

FIG. 3D illustrates a semiconductor device with isolation by a backside via. In some embodiments, the silicon controlled rectifier, the diode, and the bipolar junction transistor are isolated by a backside via 380, which extends from the shallow trench isolation to the backside of the semiconductor device. This backside via 380 serves as an electrical isolation pathway, ensuring that the SCR, diode, and BJT operate independently without any electrical interference from other components on the frontside of the device. The isolation provided by the backside via 380 maintains the integrity and reliability of the active elements, and prevents unwanted current leakage and cross-talk that could degrade the performance of the semiconductor device.

By utilizing a backside via 380, e.g., BV 380, for isolation, the semiconductor device achieves a more streamlined and efficient layout. This design eliminates the need for vias extending from the frontside, thereby reducing the complexity of the frontside circuitry and minimizing potential points of failure. The absence of frontside vias simplifies the manufacturing process, leading to improved yield rates and lower production costs. Additionally, this configuration enhances thermal management, as heat generated by the SCR, diode, and BJT can be effectively dissipated through the backside via 380 directly to the backside of the device. Efficient heat dissipation is crucial for maintaining optimal operating temperatures, which in turn ensures the longevity and stable performance of the semiconductor components.

Furthermore, the integration of backside via 380 aligns with advanced semiconductor packaging techniques that prioritize compactness and high-density integration. By centralizing the electrical isolation on the backside, the device can achieve higher levels of functionality and performance within a smaller footprint. This is particularly advantageous for applications requiring high-speed switching and robust protection mechanisms, where precise and reliable isolation is paramount. The use of backside vias also supports the scalability of the semiconductor device, allowing for seamless integration into more complex and densely packed electronic systems without compromising on electrical isolation or thermal efficiency.

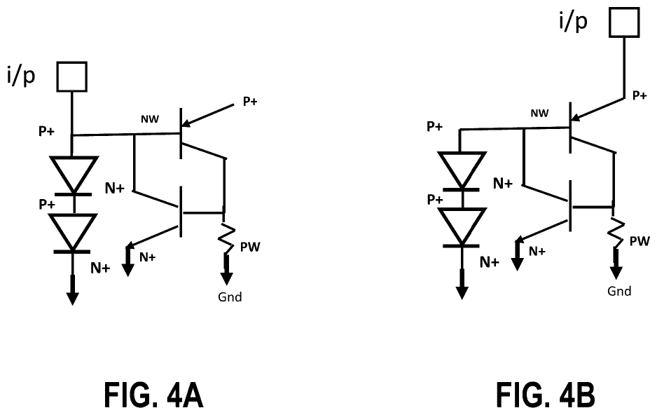

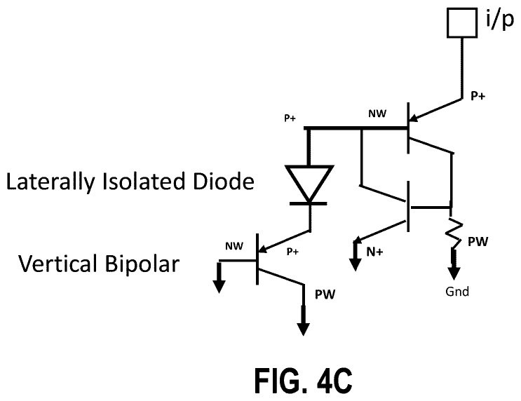

FIGS. 4A-4D illustrates exemplary circuitry of the semiconductor device shown in FIGS. 3A-3D, respectively.

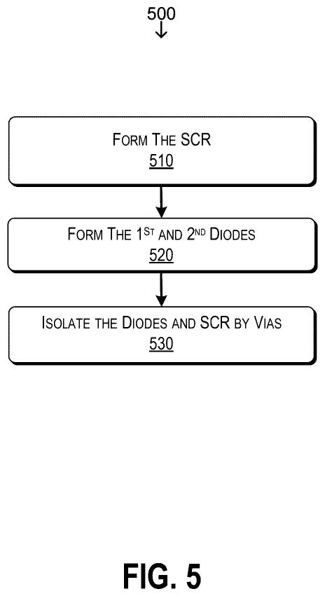

FIG. 5 illustrates a block diagram of a method 500 for forming the semiconductor device, in accordance with some embodiments. As shown by block 510, an SCR is formed.

As shown by block 520, a first diode and a second diode are formed.

As shown by block 530, the SCR, the first diode and the second diode are isolated by a set of vias.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a silicon controlled rectifier (SCR) comprising:
a P-type doped region,
an N-type doped region;
an N-well region;
a P-well region adjacent to the N-well region, wherein the N-well region and the P-well region are located below the P-type doped region and the N-type doped region; and
a set of shallow trench isolation (STI) below the P-type doped region and the N-type doped region and within the N-well region and the P-well region; and
a first diode and a second diode coupled in series to the SCR, wherein the SCR, the first diode and the second diode are isolated by a set of vias extended vertically from a frontside of the semiconductor device to a backside of the semiconductor device.

2. The semiconductor device of claim 1, further comprising gate regions on two ends of the N-type doped region and the P-type doped region.

3. The semiconductor device of claim 1, further comprising a backside interlayer dielectric below the N-well region and the P-well region.

4. The semiconductor device of claim 1, wherein each of the N-type doped region and the P-type doped region further comprises a plurality of nano-sheet channels between a corresponding doped region and a gate region.

5. The semiconductor device of claim 4, wherein the plurality of nano-sheet channels comprises alternative layers extended horizontally between the corresponding doped region and the gate region.

6. The semiconductor device of claim 5, wherein the alternative layers include silicon.

7. The semiconductor device of claim 1, further comprising:
a liner over sidewalls of each of the set of vias, wherein the liner includes SiN.

8. The semiconductor device of claim 7, wherein:
the set of vias are configured to provide electrical connection between the frontside to the backside.

9. A method of fabricating a semiconductor device, the method comprising:
forming a silicon controlled rectifier (SCR) comprising:
forming a set of shallow trench isolation (STI);
forming an N-well region;
forming a P-well region adjacent to the N-well region; and
forming a P-type doped region and an N-type doped region;
forming a first diode and a second diode coupled in series to the SCR; and
isolating the SCR, the first diode and the second diode by a set of vias extended vertically from a frontside of the semiconductor device to a backside of the semiconductor device,
wherein:
the N-well region and the P-well region are located below the P-type doped region and the N-type doped region; and
the set of STI is located below the P-type doped region and the N-type doped region and within the N-well region and the P-well region.

10. The method of claim 9, further comprising forming gate regions on opposite ends of the N-type doped region and the P-type doped region.

11. The method of claim 9, further comprising forming a backside interlayer dielectric below the N-well region and the P-well region.

12. The method of claim 9, wherein forming each of the N-type doped region and the P-type doped region further comprises forming a plurality of nano-sheet channels between a corresponding doped region and a gate region.

13. The method of claim 12, wherein forming the plurality of nano-sheet channels comprises extending alternative layers horizontally between the corresponding doped region and the gate region.

14. The method of claim 13, wherein the alternative layers include silicon.

15. The method of claim 9, further comprising:
forming a liner over sidewalls of each of the set of vias, wherein the liner includes SiN.

16. The method of claim 15, further comprising:
providing electrical connections between the frontside and the backside by the set of vias.

17. A semiconductor device, comprising:
a silicon controlled rectifier (SCR);
a diode coupled in series to the SCR; and
a bipolar junction transistor coupled in series to the diode,
wherein the SCR and the diode are isolated by a set of vias and a set of shallow trench isolation, and wherein well regions of the SCR and the bipolar junction transistor are coupled.

18. The semiconductor device of claim 17, wherein the SCR comprises:
a P-type doped region and an N-type doped region;
an N-well region; and
a P-well region adjacent to the N-well region, wherein the N-well region and the P-well region are located below the P-type doped region and the N-type doped region, wherein the set of shallow trench isolation is located below the P-type doped region and the N-type doped region and within the N-well region and the P-well region.

19. The semiconductor device of claim 18, further comprising:
gate regions on opposite ends of the N-type doped region and the P-type doped region; and
a backside interlayer dielectric below the N-well region and the P-well region.

20. The semiconductor device of claim 18, wherein each of the N-type doped region and the P-type doped region further comprises a plurality of nano-sheet channels between a corresponding doped region and a gate region.
